(19) United States
(12) Patent Application Publication
(10) Pub. No.: US 2019/0214274 A1
(43) Pub. Date: Jul. 11, 2019

(54) INSULATING CONTACTING SPACER

(71) Applicant: STMicroelectronics (Grenoble 2) SAS, Grenoble (FR)

(72) Inventor: David AUCHERE, Meylan (FR)

(73) Assignee: STMicroelectronics (Grenoble 2) SAS, Grenoble (FR)

(21) Appl. No.: 16/240,220

(22) Filed: Jan. 4, 2019

(30) Foreign Application Priority Data
Jan. 5, 2018 (FR) 1850083

(51) Int. Cl. H01L 21/48; H01L 21/56; H01L 23/00; H01L 25/065; H01L 23/498; H05K 1/11; H01L 23/31

(52) U.S. Cl. CPC H01L 21/486; H01L 21/56; H01L 24/17; H01L 25/0655; H01L 2224/73103; H05K 1/113; H01L 23/3107; H05K 2201/09563; H01L 23/49827

(57) ABSTRACT

An insulating spacer provides electrical connection between first contacts of a package for an electronic chip and second contacts of a connector board. The insulating spacer includes conductive vias having rectilinear axes parallel to one another which extend between the first and second contacts. The package for an electronic chip is mounted to one side of the insulating spacer and the connector board is mounted to an opposite side of the insulating spacer.

### PRIORITY CLAIM

This application claims the priority benefit of French Application for Patent No. 1850083, filed on Jan. 5, 2018, the content of which is hereby incorporated by reference in its entirety to the maximum extent allowable by law.

### TECHNICAL FIELD

The present disclosure concerns electronic chip packages and more particularly the assembly and the connection of electronic chip packages to a printed circuit board.

### BACKGROUND

FIG. 1 is a cross-section view of a package 100, for example, rectangular, assembled on a connector board 200, for example, a printed circuit board, via solder balls 300. Package 100 may comprise one or a plurality of electronic chips 101 (two chips 101 are shown in FIG. 1). Each chip 101 comprises contacts 101A on its lower surface (only one contact 101A is shown in FIG. 1).

Package 100 is formed of an interconnect or lead frame 110 forming the base of package 100, and for example of lateral walls 120 forming the lateral surfaces of package 100. The assembly is generally encapsulated in an epoxy resin 130. Resin 130 enables to protect chips 101 against impurities, short-circuits, etc.

Lead frame 110 comprises, on its upper surface, pads 111 and, on its lower surface, contacts 113 (only one pad 111 and one contact 113 are shown in FIG. 1). Each pad 111 is connected to one or a plurality of contacts 113 by vias and metallizations 115. As a variation, a plurality of pads 111 may be connected to a same contact 113. Pads 111 are intended to be connected to contacts 101A of chips 101, for example, via solder balls 103.

Contacts 113 are intended to be connected to pads of a printed circuit board 200 comprising, at its upper surface, pads 201 (only one pad 201 is shown in FIG. 1). Each contact 113 of the package is connected to a pad 201 of board 200 via solder balls 300.

It would be desirable to at least partly improve certain aspects of the elements of connection of packages to printed circuit boards.

### SUMMARY

Thus, an embodiment provides an insulating spacer providing contacts between a package for an electronic chip and a connector board, crossed by conductive vias having rectilinear axes parallel to one another.

According to an embodiment, the spacer has a thickness in the range from 100 μm to 1 mm.

According to an embodiment, the vias have a cross-section inscribed within a circle having a diameter in the range from 100 μm to 1 mm.

According to an embodiment, the vias have a cylindrical shape.

According to an embodiment, the vias have a conical shape.

According to an embodiment, the vias are made of metal or of a conductive alloy.

According to an embodiment, the spacer is formed of an insulating resin.

Another embodiment provides an electronic device comprising: an electronic chip package; a spacer; and a printed circuit board.

According to an embodiment, the device comprises a display and the package comprises at least one optical unit, the spacer being positioned to bring the optical unit closer to the display.

Still another embodiment provides a method of manufacturing an insulating contacting spacer.

According to an embodiment, the manufacturing method is a method of manufacturing an insulating spacer providing contacts between an electronic chip package and a connector board, comprising the successive steps of: depositing on an insulating mask, forming the spacer, comprising cavities, on a surface of the package comprising contacts to be transferred onto the connector board; and forming vias in the cavities of the mask.

According to an embodiment, the insulating mask is formed by chemical etching or by laser etching of an insulating layer.

According to an embodiment, the insulating mask is deposited by means of a tool injecting an insulating material into a mold.

According to an embodiment, the vias are formed by filling the cavities with solder paste.

According to an embodiment, the vias are formed by filling the cavities with solder balls and then by melting said balls.

### BRIEF DESCRIPTION OF THE DRAWINGS

The foregoing and other features and advantages will be discussed in detail in the following non-limiting description of specific embodiments in connection with the accompanying drawings, wherein:

FIG. 1, previously described, is a cross-section view illustrating elements of connection of a package to a printed circuit board;

FIG. 2 is a cross-section view of an electronic device;

FIG. 3 is a cross-section view illustrating other elements of connection of a package to a printed circuit board;

FIG. 4 is a cross-section view illustrating an embodiment of means of connection of a package to a printed circuit board;

FIGS. 5A to 5F are simplified cross-section views illustrating steps of an embodiment of the connection means of the device of FIG. 4;

FIG. 6 is a cross-section view illustrating an alternative embodiment of the connection means of FIG. 4; and

FIG. 7 is a cross-section view of an electronic device.

### DETAILED DESCRIPTION

The same elements have been designated with the same reference numerals in the different drawings. For clarity, only those steps and elements which are useful to the understanding of the described embodiments have been shown and are detailed. In particular, the design of lead frame 110 is not discussed.

In the following description, when reference is made to terms qualifying relative position such as “upper”, “lower”, etc., reference is made to the orientation of the drawings. The terms “in the order of” are used herein to designate a tolerance of plus or minus 10%, preferably of plus or minus 5%, of the value in question.

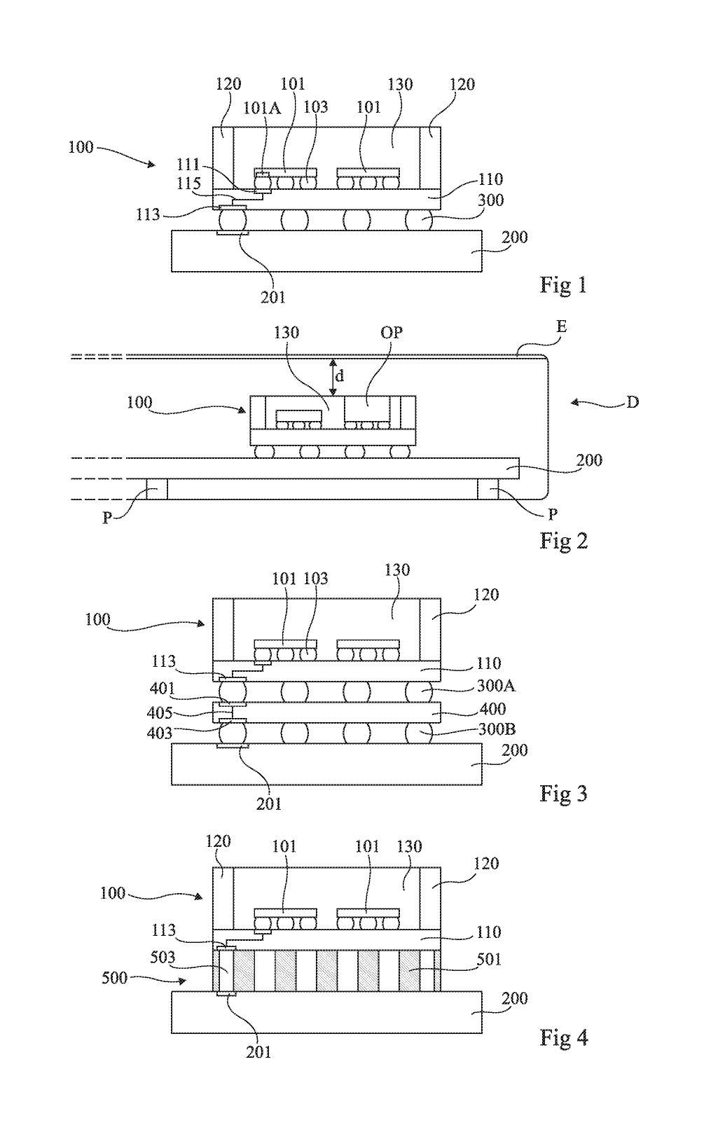

FIG. 2 is a cross-section view of a portion of an electronic device D, for example, a cell phone, illustrating an example of use of a device such as that in FIG. 1. Device D comprises a display E at its upper surface. The assembly of FIG. 1 is arranged in electronic device D, connector board 200 being on the lower surface side, via feet P, and package 100 being on the display side. In this configuration, the upper surface of package 100 is arranged at a distance d from display E.

In this embodiment, one of chips 101 is an optical unit OP comprising an optical sensor or an optical emitter at its upper surface. Thus, the upper surface of unit OP is not covered with resin 130 to avoid preventing its operation. A disadvantage of this device is that optical unit OP is distant from the display by distance d, which may adversely affect its good operation.

It would thus be desirable to increase the thickness of the assembly of FIG. 1, for example in order to decrease distance d in the embodiment of FIG. 1. The thicknesses of package 100 and of printed circuit board 200 being generally determined by the methods of manufacturing these elements, increasing the thickness of the connection means is the most convenient solution to increase the thickness of such a device. However, increasing the size of the solder balls would imply, to respect the height-to-width ratio and the insulation between two neighboring balls, increasing the widths of package 100 and of printed circuit board 200.

FIG. 3 is a cross-section view of package 100 of FIG. 1 assembled on printed circuit board 200 via an interposer 400 and solder balls 300A, 300B. Balls 300A and 300B are of the type of the solder balls 300 illustrated in relation with FIG. 1.

Interposer 400 is a plate of the type of interconnection gate 110 of package 100. Thus, interposer 400 comprises, at its upper surface, pads 401 and, at its lower surface, contacts 403. Each pad 401 is connected to one or a plurality of contacts 403 via vias 405.

Package 100 is assembled on the interposer via solder balls 300A. More particularly, each contact 113 of package 100 is connected to a pad 401 of interposer 400 by a solder ball 300A.

Interposer 400 is itself assembled on printed circuit board 200 via balls 300B. More particularly, each contact 403 of interposer 400 is connected to a pad 201 of board 200 by a ball 300B.

FIG. 3 shows a solution enabling to use two stacked balls (via an interposer) of smaller diameter than those which would be necessary in the configuration of FIG. 1. However, the ball diameter is only little variable, as well as the thickness of an interposer, which depends on the manufacturing method thereof. Further, adding an interposer implies an additional design cost.

FIG. 4 is a cross-section view of an embodiment of package 100 of FIG. 1 assembled on printed circuit board 200 via an embodiment of a contacting spacer 500.

Spacer 500 is an insulating layer 501 crossed by rectilinear vias 503. Insulating layer 501 is for example made of an electrically-insulating resin, for example, an epoxy resin. Vias 503 are all parallel to one another. Vias 503 are for example made of metal or of a conductive alloy, and have a cross-section which is inscribed within a circle having a diameter close that of contact 113, for example, in the range from 100 μm to 1 mm, for example, in the order of 300 μm. As an example, via 503 are cylindrical vias.

Spacer 500 is positioned between package 100 and printed circuit board 200. Further, each contact 113 of package 100 is connected to one or a plurality of vias 201 of board 200 via a via 503.

An advantage of this embodiment is that the thickness of spacer 500 can easily be modulated. The thickness of spacer 500 is, for example, in the range from 100 μm to 1 mm.

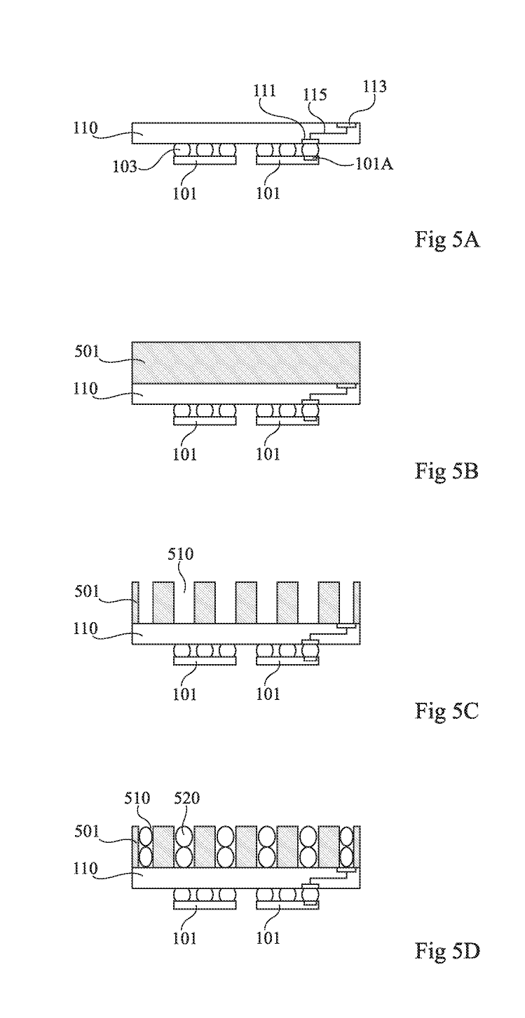

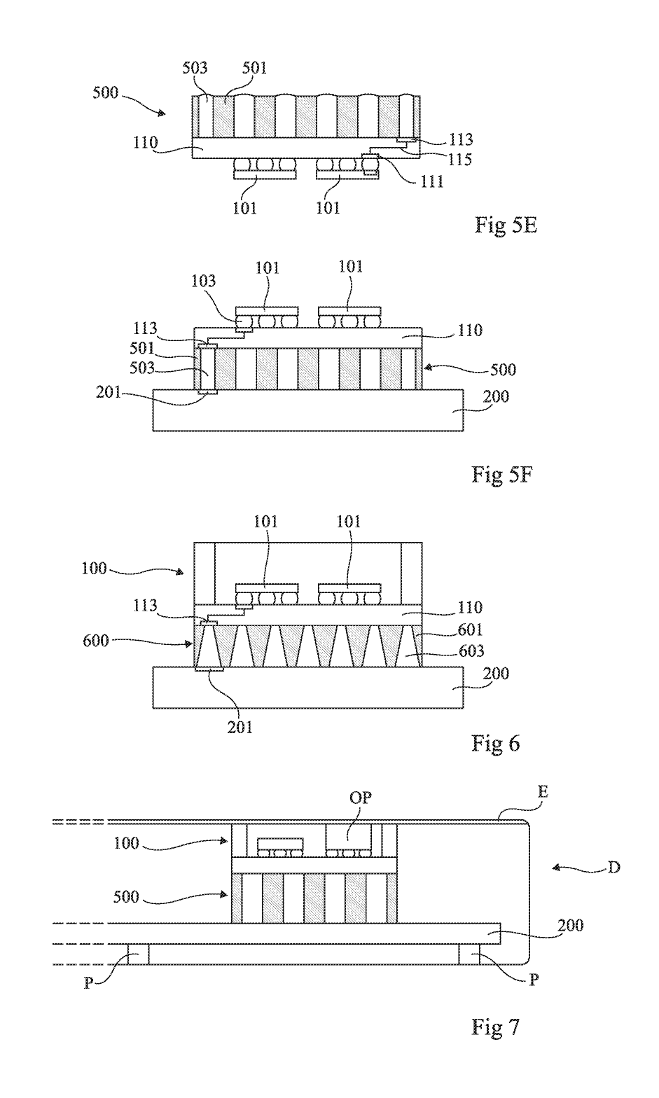

FIGS. 5A to 5F are cross-section views illustrating the implementation of steps of an embodiment of a method of manufacturing a package 100 described in relation with FIG. 4.

At the step of FIG. 5A, chips 101 are assembled on lead frame 110 of package 100 comprising pads 111, contacts 113, and vias 115. More particularly, each contact 101A of chips 101 is connected to a pad 111 by a solder ball 103.

The assembly formed by lead frame 110 and chips 101 is flipped to position contacts 113 of lead frame 110 upwards.

At the step of FIG. 5B, an insulating layer 501 is deposited on contacts 113 of lead frame 110 and forms insulating layer 501 of spacer 500. Layer 501 has a thickness in the range from 100 μm to 1 mm, for example, in the order of 600 μm.

At the step of FIG. 5C, cavities 510 crossing layer 501 are formed. Each cavity 510 exposes a contact 113 of lead frame 110. Layer 501 then forms a mask 501 exposing contacts 113. Cavities 510 are for example formed by means of a laser, for example, by a TMV (“Through Mold Via”) method or by chemical etching.

As a variation, cavities 510 may be directly formed during the deposition of layer 500. As an example, the deposition step may comprise using a tool injecting resin into a mold.

At the step of FIG. 5D, cavities 510 are filled with solder balls 520. Each cavity 510 may accommodate one or a plurality of solder balls 520 according to its dimensions. Solder balls 520 are, for example, made of metal or of a conductive alloy.

At the step of FIG. 5E, solder balls 520 are melted to totally fill cavities 510 and to form vias 503 shown in relation with FIG. 4. Each via 503 thus has one of its ends connected to a contact 113.

As a variation, cavities 510 may be filled with solder paste.

The volume of solder balls 520 is for example selected to correspond to that of cavities 510, otherwise a step of planarizing the surface of layer 501 to take it down to the level of the surface of vias 503 is provided.

At the step of FIG. 5F, the device described in relation with FIG. 5E is assembled on integrated circuit card 200. More particularly, each via 503 is connected to a pad 201 of the integrated circuit card. FIG. 5E illustrates the obtained device flipped to position chips 101 upwards.

In subsequent manufacturing steps, the manufacturing of package 100 is completed. More specifically, lateral walls 120 are formed on lead frame 110 and package 100 is then filled with resin 130 enabling to protect chips 101.

An advantage of this method is that it adapts to the parallel manufacturing of a plurality of packages. More particularly, by positioning a plurality of packages 100 on a same plate, a spacer 500 may be formed on each package 100 at the same time.

FIG. 6 is a cross-section view of an alternative embodiment 600 of spacer 500 of FIG. 4. Spacer 600 is formed of an insulating layer 601 crossed by vias 603. Insulating layer 601 is of the type of layer 501 described in relation with FIG. 4. Vias 603 have a conical shape, that is, their upper surface has a smaller area than their lower surface.

An advantage of this embodiment is that it eases the filling of the cavities formed in the insulating layer during the spacer manufacturing process. Another advantage is that it enables to connect contacts and pads of different sizes.

FIG. 7 is a cross-section view of device D of FIG. 3 where an assembly of FIG. 4 has been arranged. By adapting the thickness of spacer 500 to device D, the upper surface of optical unit OP is positioned against display E of device D.

Specific embodiments have been described. Various alterations and modifications will occur to those skilled in the art. In particular, lateral walls 120 and resin 130 may be arranged during a step preceding the step described in relation with FIG. 5A.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An insulating spacer for providing an electrical connection between first contacts of a package for an electronic chip and second contacts of a connector board, comprising a plurality of conductive vias having rectilinear axes parallel to one another, each via having a first end in direct physical and electrical contact with one of the first contacts and a second end in direct physical and electrical contact with one of the second contacts.

2. The spacer of claim 1, further comprising an insulating block through which the plurality of conductive vias pass, said insulating block having a thickness in a range from 100 μm to 1 mm.

3. The spacer of claim 1, wherein the vias have a cross-section which is inscribed with a circle having a diameter in the range from 100 μm to 1 mm.

4. The spacer of claim 1, wherein the vias have a cylindrical shape.

5. The spacer of claim 1, wherein the vias have a conical shape.

6. The spacer of claim 1, wherein the vias are made of one of a metal and a conductive alloy.

7. The spacer of claim 1, further comprising an insulating block through which the plurality of conductive vias pass, said insulating block formed of an insulating resin.

8. An electronic device, comprising:
an electronic chip package including first contacts;
a printed circuit board including second contacts; and
a spacer positioned between the electronic chip package and the printed circuit board;
wherein the spacer comprises a plurality of conductive vias having rectilinear axes parallel to one another, each via having a first end in direct physical and electrical contact with one of the first contacts and a second end in direct physical and electrical contact with one of the second contacts.

9. The electronic device of claim 8, further comprising an insulating block through which the plurality of conductive vias pass, said insulating block having a thickness in a range from 100 μm to 1 mm.

10. The electronic device of claim 8, wherein the vias have a cross-section which is inscribed with a circle having a diameter in the range from 100 μm to 1 mm.

11. The electronic device of claim 8, wherein the vias have a cylindrical shape.

12. The electronic device of claim 8, wherein the vias have a conical shape.

13. The electronic device of claim 8, wherein the vias are made of one of a metal and a conductive alloy.

14. The electronic device of claim 8, further comprising an insulating block through which the plurality of conductive vias pass, said insulating block formed of an insulating resin.

15. The electronic device of claim 8, further comprising a display, and wherein the package comprises at least one optical unit, the spacer being positioned to paste the optical unit to the display.

16. A method, comprising:
depositing a layer of insulating material on a surface of an electronic chip package including first contacts;
forming cavities extending through the layer of insulating material to expose the first contacts on the surface of the electronic chip package;
filling the cavities with conductive vias having a first end in direct physical and electrical contact with the first contacts; and
mounting a connector board including second contacts to the layer of insulating material with the second contacts in direct physical and electrical contact with second ends of the conductive vias.

17. The method of claim 16, further comprising performing one of a chemical etching and a laser etching of the layer of insulating material for form said cavities.

18. The method of claim 16, wherein depositing and forming comprise injecting an insulating material into a mold.

19. The method of claim 16, wherein forming the conductive vias comprises filling the cavities with solder paste.

20. The method of claim 16, wherein forming the conductive vias comprises:
filling the cavities with solder balls; and
melting said solder balls.
